(19) United States
(12) Patent Application Publication
(10) Pub. No.: US 2012/0242516 A1
(43) Pub. Date: Sep. 27, 2012

(54) WUBI INPUT SYSTEM AND METHOD

(75) Inventors: Jing Zhang, Shenzhen (CN); Xin Deng, Shenzhen (CN)

(73) Assignee: Tencent Technology (Shenzhen) Company Limited, Shenzhen (CN)

(21) Appl. No.: 13/480,323

(22) Filed: May 24, 2012

Related U.S. Application Data
(63) Continuation of application No. PCT/CN2010/076479, filed on Aug. 31, 2010.

(30) Foreign Application Priority Data
Dec. 2, 2009 (CN) 200910194363.2

(51) Int. Cl. H03M 11/00

(52) U.S. Cl. 341/28

(57) ABSTRACT

A Wubi input system, includes a cache word library, to store word information and index information of frequently-used words associated with one-keystroke codes and two-keystroke codes; cache word library, to store word information and index information of frequently-used words associated with one-keystroke codes and two-keystroke codes; and a word retrieving module, to retrieve at least one word from the cache word library according to the index information in the cache word library when a one-keystroke code or two-keystroke code is inputted; and to retrieve at least one word from the core word library according to the index information in the cache word library when a three-keystroke code or four-keystroke code is inputted.

### CROSS-REFERENCE TO RELATED APPLICATIONS

This application is a continuation-in-part of International Application No. PCT/CN2010/076479 (filed Aug. 31, 2010), which claims priority to Chinese Application No. 200910194363.2 (filed Dec. 2, 2009), the contents of which are incorporated herein by reference.

### FIELD OF THE INVENTION

The present invention relates to an input method, and more particularly, to a Wubi input system and method.

### BACKGROUND OF THE INVENTION

Wubizixing input method, also known as five stroke character model input method, often abbreviated to simply Wubi or Wubi Xing, is a Chinese character input method for encoding according to the structure of Chinese characters invented by professor Wang Yongmin, and is one of most common Chinese character input methods used by China and some countries of Southeast Asia at present.

The basic principle of Wubi is as follows. Chinese characters are all formed from strokes or radicals. In order to input the Chinese characters, some frequently-used basic units, called character components, are split from Chinese characters. A component may be a radical of a Chinese character, or part of a radical, or even a stroke. After being taken out, the components are classified based on a certain rule. Subsequently, the components are assigned to keys of the keyboard according to scientific principles, and serve as basic units for inputting Chinese characters. There are 130 kinds of basic components in Wubi input method. Considering deformations of some basic components, there are 200 kinds altogether. These components are assigned to 25 keys except “Z”. When to input a Chinese character, keys corresponding to components on the keyboard are typed in an order in which the components would be written by hand, then a Wubi code is formed. The system searches a Chinese character library of Wubi input method for the desired Chinese character according to the Wubi code formed based on inputted components.

The Wubi input method can find out a user-expected word quickly because of its low rate of coincidence code. In case that the user is familiar with the Wubi input method, the input speed can be increased greatly. It is needed for the user to expertly split the words, and it generally needs three to four Wubi keystrokes to quickly determine a desired word. When being inexperienced, a user can only obtain a large number of candidate words through a one-keystroke code or two-keystroke code (a n-keystroke code refers to a Wubi code including n keystrokes), and find the desired word by screening. Thus the input speed is decreased.

### SUMMARY OF THE INVENTION

In view of above, it is necessary to provide a Wubi input system and method capable of increasing input speed of a user to solve the problem in a conventional Wubi input method that the rate of coincidence code is high in case of inputting a one-keystroke code or two-keystroke code, which influences the input seed.

The Wubi input system provided by embodiments of the present invention includes:

a cache word library, to store word information and index information of frequently-used words associated with one-keystroke codes and two-keystroke codes;

a core word library, to store word information and index information of words associated with all Wubi codes;

a word retrieving module, to retrieve at least one word from the cache word library according to the index information in the cache word library when a one-keystroke code or two-keystroke code is inputted; and to retrieve at least one word from the core word library according to the index information in the cache word library when a three-keystroke code or four-keystroke code is inputted.

Preferably, the cache word library includes:

a cache encoding index area, to store the index information of the frequently-used words;

a cache word storage area, to store the word information of the frequently-used words, wherein all frequently-used words are stored in an order according to their indexes, for each frequently-used word, the first two keystrokes of its Wubi code are taken as its index, and for each set of frequently-used words that have the same first two keystrokes of Wubi code, the set of frequently-used words is stored in a descending order of their word frequencies.

Preferably, the core word library includes:

a core encoding index area, to store the index information of words associated with all Wubi codes;

a core word storage area, to store the word information of words associated with all Wubi codes, wherein all words are stored in an order according to their indexes; for each word, the first three keystrokes of its Wubi code are taken as its index; and for each set of words that have the same first three keystrokes of Wubi code, the set of words is stored in a descending order of their word frequencies.

Preferably, the word retrieving module includes:

an index calculating module, to obtain index information according to a inputted Wubi code;

a candidate word output module, to obtain and display at least one word according to the index information.

Preferably, the method further includes:

a determining module, to determine whether the cache word library includes a user-expected word based on a inputted one-keystroke code or two-keystroke code.

The Wubi input method provided by embodiments of the present invention includes:

receiving a inputted Wubi code;

retrieving at least one word from a cache word library when the inputted Wubi code is a one-keystroke code or two-keystroke code, wherein the cache word library stores wording information and index information of frequently-used words associated with one-keystroke codes or two-keystroke codes;

retrieving at least one word from a core word library when the inputted Wubi code is a three-keystroke code or four-keystroke code, wherein the core word library stores wording information and index information of words associated with all Wubi codes.

Preferably, after retrieving at least one word from the cache word library, further including:

determining whether the cache word library includes a user-expected word, if the cache word library does not include the user-expected word, retrieving the user-expected word from the core word library.

Preferably, retrieving at least one word from the cache word library includes:

for each word in the cache word library as an index, taking the first two keystrokes of its Wubi code as its index, storing the words in the cache word library in an order according to their indexes, for each set of words in the cache word library that have the same frist two keystrokes of Wubi code, storing the set of words in the cache word library in a descending order of their word frequencies, converting the inputted Wubi code into index information, retrieving and displaying at least one word in above order according to the index information.

Preferably, retrieving at least one word from the core word library includes:

for each word in the core word library, taking the first three keystrokes of its Wubi code as its index, storing all words in the core word library in an order according to their indexes, for each set of words that have the same first three keystrokes of Wubi code, storing the set of words in a descending order of their word frequencies;

if the inputted Wubi code is a three-keystroke code, converting the three-keystroke code into index information, obtaining at least one word according to the index information and displaying the at least one word in a descending order of their word frequencies;

if the inputted Wubi code is a four-keystroke code, filtering words the fourth keystroke of Wubi code of which does not match the fourth keystroke of the four-keystroke code from words obtained based on the first three keystrokes of the four-keystroke code, then obtaining all words associated with the four-keystroke code, displaying the words associated with the four-keystroke code in a descending order of their word frequencies.

Preferably, retrieving at least one word from the core word library further includes:

if the inputted Wubi code is a one-keystroke code or two-keystroke code, converting the one-keystroke code or two-keystroke code into index information, obtaining at least one word according to the index information, and retrieving and displaying the at least one word in a storage order of the at least one word in core word library.

As can be seen from the above technical solutions, after a cache word library is added, it is possible to preferably search the cache word library according to an input of a user. When the user inputs a one- keystroke code or two- keystroke code, frequently-used words are displayed, the hit rate of a user-expected word is increased and the input speed of Wubi input method is increased without searching a large number of words.

Because the one-keystroke code or two-keystroke code are preferably processed to retrieve corresponding words from the cache word library, when a user inputs a one-keystroke code or two-keystroke code, frequently-used words are displayed, hit rate of a user-expected word is increased and input speed of Wubi input method is increased without searching a large number of words.

### BRIEF DESCRIPTION OF DRAWINGS

FIG. 1 is a schematic diagram illustrating a Wubi input system according to a first embodiment.

FIG. 2 is a flowchart illustrating a Wubi input method according to the first embodiment.

FIG. 3 is a schematic diagram illustrating a Wubi input system according to a second embodiment.

FIG. 4 is a flowchart illustrating a Wubi input method according to the second embodiment.

### DETAILED DESCRIPTION OF THE INVENTION

### The First Embodiment

As shown in FIG. 1, FIG. 1 is a schematic diagram illustrating a Wubi input system according to the first embodiment of the present invention. The Wubi input system includes: a word retrieving module 100, a core word library 200 and a cache word library 300. The core word library 200 is configured to store word information and index information of all Wubi codes. The cache word library 300 is configured to store word information and index information of frequently-used words associated with one-keystroke codes and two-keystroke codes. When a one-keystroke code or two-keystroke code is inputted, the word retrieving module 100 is configured to retrieve at least one word from the cache word library 300 according to the index information in the cache word library 300. When a three-keystroke code or four-keystroke code is inputted, the word retrieving module 100 is configured to retrieve at least one word from the core word library 200 according to the index information in the core word library 300.

The word retrieving module 100 includes an index calculating module 110 and a candidate word output module 120. The index calculating module 110 is configured to convert a Wubi code to index information according to the input of a user. For example, the index calculating module 110 converts a one-keystroke code or two-keystroke code to index information for retrieving at least one word from the cache word library 300, and converts a three-keystroke code or four-keystroke code to index information for retrieving at least one word from the core word library 200. The candidate word output module 120 is configured to, according to the index information, obtain the at least one word and then display and output the at least one word.

The core word library 200 includes a core encoding index area 210 and a core word storage area 220. The core encoding index area 210 is configured to store the index information of word information of all Wubi codes. The core word storage area 220 is configured to store word information of all Wubi codes. The first three keystrokes of Wubi code of each word are taken as an index. All words are stored in order according to their indexes. As to words of which the first three keystrokes of Wubi code are the same, the storage is carried out according to their word frequencies in a descending order.

The cache word library 300 includes a cache encoding index area 310 and a cache word storage area 320. The cache encoding index area 310 is configured to store the index information of the frequently-used words. The cache word storage area 320 is configured to store the word information of the frequently-used words. With respect to the frequently-used words, the first two keystrokes of Wubi code of each of them are taken as an index, and the frequently-used words are stored in a descending order of their word frequencies.

In the embodiment, the core encoding index area 210 and the cache encoding index area 310 are both a continuous array area. Each element of the array needs 4 bytes. The starting poison of words associated with each Wubi code in the core word storage area 220 or the cache word storage area 320 is recorded in the array.

The index information is the starting position, of words, stored in the array. Correspondingly, the index information stored in the core encoding index area 210 is the starting position of words in the core word storage area 220; the index information stored in the cache encoding index area 310 is the starting position of words in the cache word storage area 320.

The core word storage area 220 and the cache word storage area 320 store word information, including Wubi codes of words, Unicode text, word frequencies of the words and other additional information. Each Wubi code of a word is used to be compared with user's input to determine whether they match each other. The Unicode text is used to display a word. The word frequency of each word may be predefined according to a statistic result, or may be updated in real time during usage. The word frequency indicates the use frequency of each word, so the word with higher word frequency is more probable to meet user's expectation. (Unicode is a text encoding standard, each character is represented by two bytes. Unicode is a character-set code of fixed-length of two bytes and multi-language, and is an existing technology)

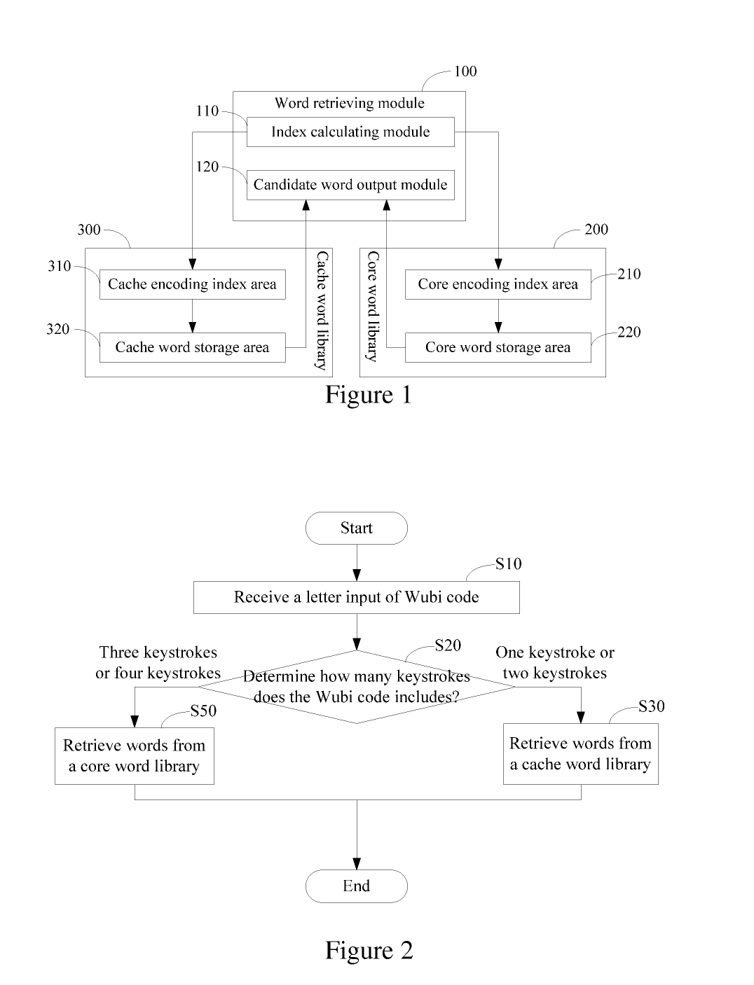

The corresponding Wubi input method, as shown in FIG. 2, includes the following processes.

S10, a Wubi code input is received. Components are assigned to 25 keys, that is, “a” to “y”, of the keyboard according to an established rule of Wubi input method. A word formed by components may be obtained according to letters inputted through keystrokes. In the processing method of the present embodiment, any combination of one to four letters from “a” to “y” inputted by the user is received.

S20, it is determined how many keystrokes the Wubi code input includes. If the Wubi code input includes one keystroke or two keystrokes, step S30 is performed, if the Wubi code input includes three keystrokes or four keystrokes, step S50 is performed.

S30, at least one word is retrieved from the cache word library 300, and then the at least one word is displayed. This step processes Wubi code inputs corresponding to one-keystroke code or two-keystroke code. Since the core word library 200 includes a large number of words, and the rate of coincidence code is higher when the Wubi code input includes one keystroke or two keystrokes, the cache word library 300 is established to collect more frequently-used words. The frequently-used words are indexed by a Wubi code input including one keystroke or two keystrokes.

For each word in the cache word library 300, the first two keystrokes of its Wubi code are taken as an index for searching the cache word library 300, so the index of the cache encoding index area 310 ranges from “a” to “yy”, and the array includes 25+25²=650 elements.

Therefore, associations between Wubi codes of one-keystroke code or two-keystroke code and array subscripts of the cache encoding index area 310 are established. strCode denotes an Wubi code inputted by a user, and length thereof may range from 1 to 4. Index denotes a converted array subscript. Then:

Index=(strCode[0]−‘a’)*(25+1)+1;

If (length of the encoding>=2) Index+=(strCode[1]−‘a’)+1.

Calculated results according to above-mentioned formula are as follows.

Wubi code: a subscript: 1

Wubi code: aa subscript: 2

Wubi code: ab subscript: 3

Wubi code: y subscript: 625

Wubi code: ya subscript: 626

Wubi code: yy subscript: 650

According to above-mentioned formula, an array subscript in cache encoding index area 310 may be obtained based on a Wubi code, and then the starting position of at least one word associated to the Wubi code in the cache word storage area 320 is obtained.

Since words in the cache word storage area 320 are indexed according to the first two keystrokes of their Wubi codes, and are sorted in an order of their word frequencies, the word retrieving module 100 retrieves at least one word from the cache word library 300 in a following mode:

When a user inputs a one-keystroke code or two-keystroke code, the starting position of at least one associated word is obtained according to an array subscript corresponding to the one-keystroke code or two-keystroke code, and then the at least one word is retrieved and displayed in accordance with an storage order of the at least one word.

Supporting that there are ten words associated with the Wubi code “aa” including “ [symbol] ” (corresponding to the Wubi code “aa”), “ [symbol] ” (corresponding to the Wubi code “aawt”), “ [symbol] ” (corresponding to the Wubi code “aahw”), “ [symbol] ” (corresponding to the Wubi code “aatk”), “ [symbol] ” (corresponding to the Wubi code “aaog”), “ [symbol] ” (corresponding to the Wubi code “aaan”), “ [symbol] ” (corresponding to the Wubi code “aauq”), “ [symbol] ” (corresponding to the Wubi code “aadg”), “ [symbol] ” (corresponding to the Wubi code “aaww”) and “ [symbol] ” (corresponding to the Wubi code “aaa”), and the ten words are stored in a descending order of their word frequencies in the cache word library 300, and then when to retrieve these words, it is possible to retrieve the words in the above order from the starting position where [symbol] is stored.

When a Wubi code including more than three keystroks is inputted, the word retrieving module 100 retrieves no word from the cache word library 300.

Based on input habits, Wubi users rarely look over more than two pages to find a candidate word. In the present embodiment, preferably, there are at most ten words associated with an index corresponding to each Wubi code, and the ten words are stored in the cache word library 300. Thus, the cache word library 300 stores at most 650*10=6500 words.

S50, at least one word is retrieved from the core word library 200, and the at least one word is displayed. The step processes Wubi code inputs corresponding to three-keystroke codes or four-keystroke codes. When a user input a three-keystroke code or four-keystroke code, the rate of coincidence code of words is lower, so the core word library 200 may be directly indexed.

For each word in the core word library 200, the first three keystrokes of its Wubi code are taken as an index for searching the core word library 200, so the index of the core encoding index area 210 ranges from “a” to “yyy”, and the array includes 25+25²+25³=16275 elements.

Therefore, one-to-one correspondences between subscripts of elements in the array and Wubi codes are established.

For example, the correspondences between Wubi codes and array subscripts of the core encoding index area 210 may be established according to the following method.

strCode denotes an Wubi code inputted by a user, and length thereof may range from 1 to 4. Index denotes a converted array subscript. Then:

Index=(strCode[0]−‘a’)*(25²+25+1)+1;

If (length of the encoding>=2)Index+=(strCode[1]−‘a’)*(25+1)+1;

If (length of the encoding>=3)Index+=(strCode [2]−‘a’)+1.

Calculated results according to above-mentioned formula are as follows.

Wubi code: a subscript: 1

Wubi code: aa subscript: 2

Wubi code: aaa subscript: 3

Wubi code: aab subscript: 4

Wubi code: aac subscript: 5

Wubi code: aad subscript: 6

Wubi code: y subscript: 15625

Wubi code: ya subscript: 15626

Wubi code: yad subscript: 15630

Wubi code: yyy subscript: 16275

The above order is a typical lexicographic order. According to above correspondences, an array subscript in core encoding index area 210 may be obtained based on a Wubi code, and then the starting position of at least one word associated with the Wubi code in the core word storage area 220 is obtained. (Being an existing technology)

The word retrieving module 100 retrieves at least one word from the core word library 200 in a following mode:

When a user inputs a three-keystroke code, words whose first three keystrokes of Wubi code are the same, are ordered in a descending order of their word frequencies, and then the words are retrieved and displayed in the above order. For instance, when a Wubi code “fnt” is inputted, if the word frequency of “ [symbol] ” corresponding to the Wubi code “fntj” is 1000, the word frequency of “ [symbol] ” corresponding to the Wubi code “fnta” is 500, the word frequency of “ [symbol] ” corresponding to the Wubi code “fntn” is 200, “ [symbol] ”, “ [symbol] ” and “ [symbol] ” are stored in the core word library 200 in the above order, and then when to retrieve these words, these words are retrieved and displayed in the above order.

When a user inputs a four-keystroke code, words the fourth keystroke of Wubi code of which doesn't match the fourth keystroke of the four-keystroke code inputted by the user are filtered from the words obtained based on the first three keystrokes of the four-keystroke code, and the remaining one or more words are all words associated with the four-keystroke code.

### The Second Embodiment

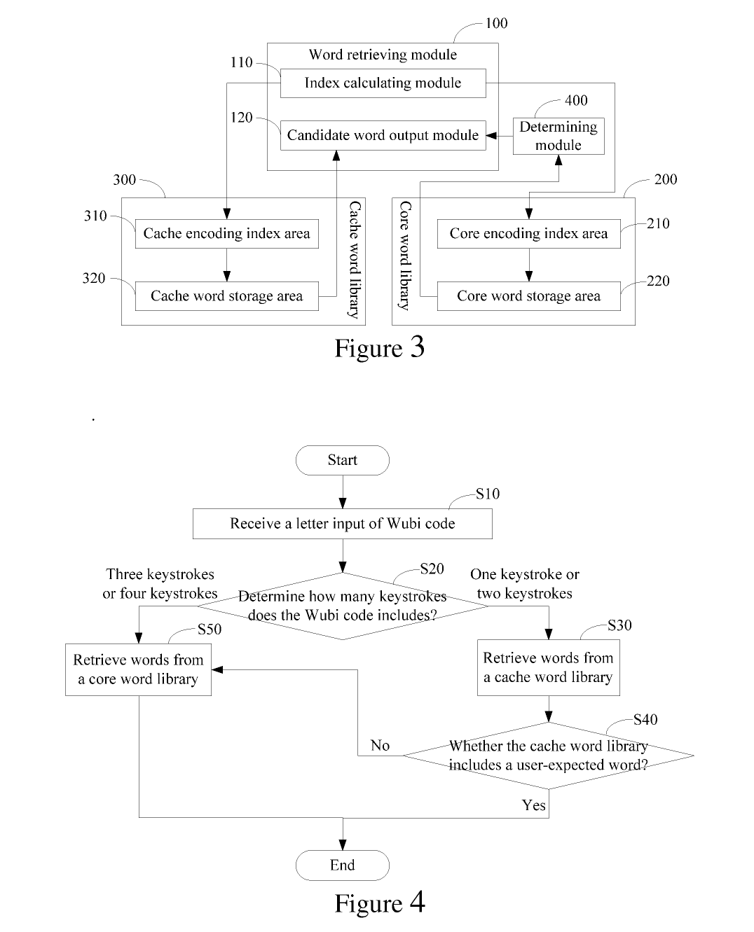

Because the rate of coincidence code of Wubi input method is lower, and after a cache word library 300 is added, the rate of coincidence code of one-keystroke code inputs or two-keystroke code inputs is reduced to a certain extent, the hit rate of word is increased. In general, the probability of obtaining expected word according to an two-keystroke code input is very high, in other words, the probability that it is required to retrieve the expected word from the core word library 200 is very low, thus the first embodiment of the present invention can retrieve a desired word quickly in most situations. However, it is impossible for a user to memorize which words are in the cache word library 300 and which words are not, hence there still exists a situation that after inputting a two-keystroke code, the user fails to find the desired word yet even when he turns to the last page. According to the processing method in above embodiment, if the desired word is not found in the cache word library 300, it is needed for the user to continue typing keystrokes to form a three-keystroke code or four-keystroke code, so as to retrieve the desired word from the core word library 200, or it is needed for the user to finish the word retrieving. Therefore, the present embodiment adds a determining module 400 on the basis of above embodiment. As shown in FIG. 3, after the user inputs a one-keystroke code or two-keystroke code, the determining module 400 determines whether the cache word library 300 includes a user-expected word. If the user is still turning pages after the last page of cache word library 300 has been looked over, it is indicated that the cache word library 300 does not include the user-expected word.

Correspondingly, as shown in FIG. 4, a step S40 is added between step S30 and step S50 on the basis of above embodiment. In step S40, it is determined that whether the cache word library 300 includes a user-expected word. If the cache word library 300 does not include the user-expected word, step S50 is performed; if the cache word library 300 includes the user-expected word, the user-expected word is outputted according to the user's command, and then the word retrieving is finished.

When a user inputs a one-keystroke code or two-keystroke code, if the cache word library 300 does not include the user-expected word, it is possible that the word is a rarely-used one, and then the user may choose to continue turning pages to find the user-expected word or to type the third or fourth keystroke.

If choosing to continue turning pages to find the user-expected word, since words stored in the cache word library 300 are limited, it is needed to turn to the core word library 200 for retrieving the user-expected word. That is to say, step S50 further includes: one-keystroke code inputs or two-keystroke code inputs are processed. When a user input a one-keystroke code or two-keystroke code, because words in the core word library 200 are ordered and indexed according to the first three keystrokes of their Wubi codes, a starting position of words associated with the one-keystroke code or two-keystroke code is obtained according to an array subscript corresponding to the one-keystroke code or two-keystroke code, and at least one word associated with the one-keystroke code or two-keystroke code are retrieved and displayed according to a storage order of the at least one word. For instance, if the user inputs a two-keystroke code “aa”, words associated with the “aa” are retrieved and displayed according to an order of their Wubi codes from “aaa”, “aab” to “aay”.

No matter what the user chooses, since the cache word library does not include the desired word, it is necessary to turn to the core word library 200 to find the desired word. If the desired word is found out, the desired word is outputted according to a user command, and the word retrieving is finished.

The foregoing description is only preferred embodiments of the present invention and the description thereof is more specific and detailed, however it can not be understand as limitation of the protection scope of the present invention. Any modification, equivalent substitution, or improvement made without departing from the spirit and principle of the present invention should be covered by the protection scope of the present invention.

1. A Wubi input system, comprising:
a cache word library, to store word information and index information of frequently-used words associated with one-keystroke codes and two-keystroke codes;
a core word library, to store word information and index information of words associated with all Wubi codes;
a word retrieving module, to retrieve at least one word from the cache word library according to the index information in the cache word library when a one-keystroke code or two-keystroke code is inputted; and to retrieve at least one word from the core word library according to the index information in the cache word library when a three-keystroke code or four-keystroke code is inputted.

2. The system according to claim 1, wherein the cache word library comprises:
a cache encoding index area, to store the index information of the frequently-used words;
a cache word storage area, to store the word information of the frequently-used words, wherein all frequently-used words are stored in an order according to their indexes, for each frequently-used word, the first two keystrokes of its Wubi code are taken as its index, and for each set of frequently-used words that have the same first two keystrokes of Wubi code, the set of frequently-used words is stored in a descending order of their word frequencies.

3. The system according to claim 2, wherein the core word library comprises:
a core encoding index area, to store the index information of words associated with all Wubi codes;
a core word storage area, to store the word information of words associated with all Wubi codes, wherein all words are stored in an order according to their indexes; for each word, the first three keystrokes of its Wubi code are taken as its index; and for each set of words that have the same first three keystrokes of Wubi code, the set of words is stored in a descending order of their word frequencies.

4. The system according to claim 1, wherein the word retrieving module comprises:
an index calculating module, to obtain index information according to a inputted Wubi code;
a candidate word output module, to obtain and display at least one word according to the index information.

5. The system according to claim 1, further comprising:
a determining module, to determine whether the cache word library includes a user-expected word based on a inputted one-keystroke code or two-keystroke code.

6. A Wubi input method, comprising:
receiving a inputted Wubi code;
retrieving at least one word from a cache word library when the inputted Wubi code is a one-keystroke code or two-keystroke code, wherein the cache word library stores wording information and index information of frequently-used words associated with one-keystroke codes or two-keystroke codes;
retrieving at least one word from a core word library when the inputted Wubi code is a three-keystroke code or four-keystroke code, wherein the core word library stores wording information and index information of words associated with all Wubi codes.

7. The method according to claim 6, after retrieving at least one word from the cache word library, further comprising:
determining whether the cache word library includes a user-expected word, if the cache word library does not include the user-expected word, retrieving the user-expected word from the core word library.

8. The method according to claim 6, wherein retrieving at least one word from the cache word library comprises:
for each word in the cache word library as an index, taking the first two keystrokes of its Wubi code as its index, storing the words in the cache word library in an order according to their indexes, for each set of words in the cache word library that have the same frist two keystrokes of Wubi code, storing the set of words in the cache word library in a descending order of their word frequencies, converting the inputted Wubi code into index information, retrieving and displaying at least one word in above order according to the index information.

9. The method according to claim 7, wherein retrieving at least one word from the cache word library comprises:
for each word in the cache word library as an index, taking the first two keystrokes of its Wubi code as its index, storing the words in the cache word library in an order according to their indexes, for each set of words in the cache word library that have the same frist two keystrokes of Wubi code, storing the set of words in the cache word library in a descending order of their word frequencies, converting the inputted Wubi code into index information, retrieving and displaying at least one word in above order according to the index information.

10. The method according to claim 6, wherein retrieving at least one word from the core word library comprises:
for each word in the core word library, taking the first three keystrokes of its Wubi code as its index, storing all words in the core word library in an order according to their indexes, for each set of words that have the same first three keystrokes of Wubi code, storing the set of words in a descending order of their word frequencies;
if the inputted Wubi code is a three-keystroke code, converting the three-keystroke code into index information, obtaining at least one word according to the index information and displaying the at least one word in a descending order of their word frequencies;
if the inputted Wubi code is a four-keystroke code, filtering words the fourth keystroke of Wubi code of which does not match the fourth keystroke of the four-keystroke code from words obtained based on the first three keystrokes of the four-keystroke code, then obtaining all words associated with the four-keystroke code, displaying the words associated with the four-keystroke code in a descending order of their word frequencies.

11. The method according to claim 7, wherein retrieving at least one word from the core word library comprises:
for each word in the core word library, taking the first three keystrokes of its Wubi code as its index, storing all words in the core word library in an order according to their indexes, for each set of words that have the same first three keystrokes of Wubi code, storing the set of words in a descending order of their word frequencies;
if the inputted Wubi code is a three-keystroke code, converting the three-keystroke code into index information, obtaining at least one word according to the index information and displaying the at least one word in a descending order of their word frequencies;
if the inputted Wubi code is a four-keystroke code, filtering words the fourth keystroke of Wubi code of which does not match the fourth keystroke of the four-keystroke code from words obtained based on the first three keystrokes of the four-keystroke code, then obtaining all words associated with the four-keystroke code, displaying the words associated with the four-keystroke code in a descending order of their word frequencies.

12. The method according to claim 10, wherein retrieving at least one word from the core word library further comprises:
if the inputted Wubi code is a one-keystroke code or two-keystroke code, converting the one-keystroke code or two-keystroke code into index information, obtaining at least one word according to the index information, and retrieving and displaying the at least one word in a storage order of the at least one word in core word library.

13. The method according to claim 11, wherein retrieving at least one word from the core word library further comprises:
if the inputted Wubi code is a one-keystroke code or two-keystroke code, converting the one-keystroke code or two-keystroke code into index information, obtaining at least one word according to the index information, and retrieving and displaying the at least one word in a storage order of the at least one word in core word library.

14. A Wubi input apparatus, comprising:
a memory;
a processor in communication with the memory; the memory storing machine readable instructions executable by the processor; wherein the machine readable instructions comprise receiving instructions and retrieving instructions:
the receiving instructions executed to receive a inputted Wubi code;
the retrieving instructions executed to retrieve at least one word from a cache word library when the inputted Wubi code is a one-keystroke code or two-keystroke code, wherein the cache word library stores wording information and index information of frequently-used words associated with one-keystroke codes or two-keystroke codes; and
to retrieve at least one word from a core word library when the inputted Wubi code is a three-keystroke code or four-keystroke code, wherein the core word library stores wording information and index information of words associated with all Wubi codes.

15. The apparatus of claim 14, wherein the memory further comprises machine readable instructions executed to determine whether the cache word library includes a user-expected word, if the cache word library does not include the user-expected word, retrieve the user-expected word from the core word library.

16. The apparatus of claim 14, wherein the retrieving instructions comprises machine readable instructions executed to,
for each word in the cache word library as an index, take the first two keystrokes of its Wubi code as its index, store the words in the cache word library in an order according to their indexes, for each set of words in the cache word library that have the same frist two keystrokes of Wubi code, store the set of words in the cache word library in a descending order of their word frequencies, convert the inputted Wubi code into index information, retrieve and display at least one word in above order according to the index information.

17. The apparatus of claim 14, wherein the retrieving instructions comprises machine readable instructions executed to,
for each word in the core word library, take the first three keystrokes of its Wubi code as its index, store all words in the core word library in an order according to their indexes, for each set of words that have the same first three keystrokes of Wubi code, store the set of words in a descending order of their word frequencies;
if the inputted Wubi code is a three-keystroke code, convert the three-keystroke code into index information, obtain at least one word according to the index information and display the at least one word in a descending order of their word frequencies;
if the inputted Wubi code is a four-keystroke code, filter words the fourth keystroke of Wubi code of which does not match the fourth keystroke of the four-keystroke code from words obtained based on the first three keystrokes of the four-keystroke code, then obtain all words associated with the four-keystroke code, display the words associated with the four-keystroke code in a descending order of their word frequencies.

18. The apparatus of claim 17, wherein the retrieving instructions further comprises machine readable instructions executed to,
if the inputted Wubi code is a one-keystroke code or two-keystroke code, convert the one-keystroke code or two-keystroke code into index information, obtain at least one word according to the index information, and retrieve and display the at least one word in a storage order of the at least one word in core word library.
